(19) United States
(12) Patent Application Publication
(10) Pub. No.: US 2024/0060724 A1
(43) Pub. Date: Feb. 22, 2024

(54) VAPOR CHAMBER AND SUPPORTING COLUMN SECUREMENT STRUCTURE THEREOF

(71) Applicant: TAIWAN MICROLOOPS CORP., New Taipei City (TW)

(72) Inventor: Chun-Hung LIN, New Taipei City (TW)

(21) Appl. No.: 18/207,034

(22) Filed: Jun. 7, 2023

(30) Foreign Application Priority Data
Aug. 18, 2022 (TW) 111208983

(51) Int. Cl. F28D 15/04

(52) U.S. Cl. CPC F28D 15/04

(57) ABSTRACT

The present disclosure discloses a vapor chamber and a supporting column securement structure thereof. The vapor chamber includes a housing and a supporting column securement structure. The housing includes a chamber. The supporting column securement structure includes a supporting mesh and a plurality of supporting columns. The supporting mesh is arranged inside the chamber and includes a plate with a plurality of mesh holes, and the plate includes a plurality of through holes formed thereon. The outer perimeter of the supporting column includes at least one positioning portion. Each supporting column penetrates through each through hole and is press-fitted at each one of the through holes via the positioning portion to be positioned on the supporting mesh. Accordingly, the supporting columns are precisely secured at the predefined locations, and the yield rate of the vapor chamber is increased.

### BACKGROUND

### Technical Field

The technical field relates to a vapor chamber, and in particular, to a supporting column structure of a vapor chamber.

### Description of Related Art

A related-art vapor chamber includes an upper cover and a lower cover attached to each other, and a chamber is formed between the upper cover and the lower cover. In addition, the internal of the chamber includes a supporting structure formed therein. Furthermore, the supporting structure is provided to maintain the chamber space of the vapor chamber to facilitate the degassing and formation of vacuum of the internal of the vapor chamber, and a working fluid is injected into the chamber.

Furthermore, the supporting structure of the vapor chamber includes a plurality of holes formed on a metal mesh, and a plurality of supporting columns are spaced apart from each other and inserted into the holes of the metal mesh while abutting against the upper and lower covers of the vapor chamber, thereby maintaining the chamber space of the vapor chamber. Accordingly, the working fluid may then repetitively perform phase change inside the chamber to dissipate heat swiftly and to achieve the effect of cooling. However, during the insertion of the supporting columns of the vapor chamber into the holes of the metal mesh, displacement tends to occur, such that the supporting columns cannot be precisely secured at the predefined locations, and the yield rate of the vapor chamber is reduced.

In view of the above, the inventor seeks to overcome the aforementioned drawbacks associated with the current technology and aims to provide an effective solution through extensive researches along with utilization of academic principles and knowledge.

### SUMMARY

An object of the present disclosure is to provide a vapor chamber and a supporting column securement structure thereof. The supporting columns are press-fitted at each one of the through holes via the positioning portion without generating any rotation, and are positioned on the supporting mesh to allow the supporting columns to be precisely secured at the predefined locations, thereby increasing the yield rate of the vapor chamber.

To achieve the aforementioned object, the present disclosure provides a vapor chamber having a housing and a supporting column securement structure. The housing includes a chamber. The supporting column securement structure includes a supporting mesh and a plurality of supporting columns. The supporting mesh is arranged inside the chamber and includes a plate with a plurality of mesh holes, and the plate includes a plurality of through holes formed thereon. An outer perimeter of each one of the supporting columns includes at least one positioning portion. Each one of the supporting columns penetrates through each one of the through holes and is press-fitted at each one of the through holes via the positioning portion to be positioned on the supporting mesh.

To achieve the aforementioned object, the present disclosure provides a supporting column securement structure of a vapor chamber, arranged inside a housing having a chamber, and the supporting column securement structure includes a supporting mesh and a plurality of supporting columns. The supporting mesh is arranged inside the chamber, and the supporting mesh includes a plate with a plurality of mesh holes, and the plate includes a plurality of through holes formed thereon. An outer perimeter of each one of the supporting columns includes at least one positioning portion. Each one of the supporting columns penetrates through each one of the through holes and is press-fitted at each one of the through holes via the at least one positioning portion to be positioned on the supporting mesh.

In comparison to a related-art vapor chamber, the supporting column securement structure of the vapor chamber of the present disclosure includes a supporting mesh and a plurality of supporting columns. The supporting mesh is arranged inside the chamber and includes a plurality of through holes. In addition, the supporting column includes a positioning portion formed at an outer perimeter thereof. Accordingly, each one of the supporting columns penetrates through each one of the through hole and is press-fitted at each one of the through holes via the positioning portion without generating any rotation, and is positioned on the supporting mesh to allow the supporting columns to be precisely secured at the predefined locations, thereby further increasing the yield rate of the vapor chamber.

### BRIEF DESCRIPTION OF THE DRAWINGS

FIG. 1 is a perspective see-through view of the vapor chamber of the present disclosure;

FIG. 2 is a perspective exploded view of the vapor chamber of the present disclosure;

FIG. 3 is a partially perspective see-through view of the supporting column securement structure of the present disclosure;

FIG. 4 is a perspective appearance view of the supporting column of the present disclosure;

FIG. 5 is a perspective appearance view of the supporting column according to another exemplary embodiment of the present disclosure;

FIG. 6 is a perspective appearance view of the supporting column according to still another exemplary embodiment of the present disclosure; and

FIG. 7 is a perspective appearance view of the supporting column according to yet another exemplary embodiment of the present disclosure.

### DETAILED DESCRIPTION

The technical contents of the present disclosure will become apparent with the detailed description of embodiments accompanied with the illustration of related drawings as follows. It is intended that the embodiments and drawings disclosed herein are to be considered illustrative rather than restrictive.

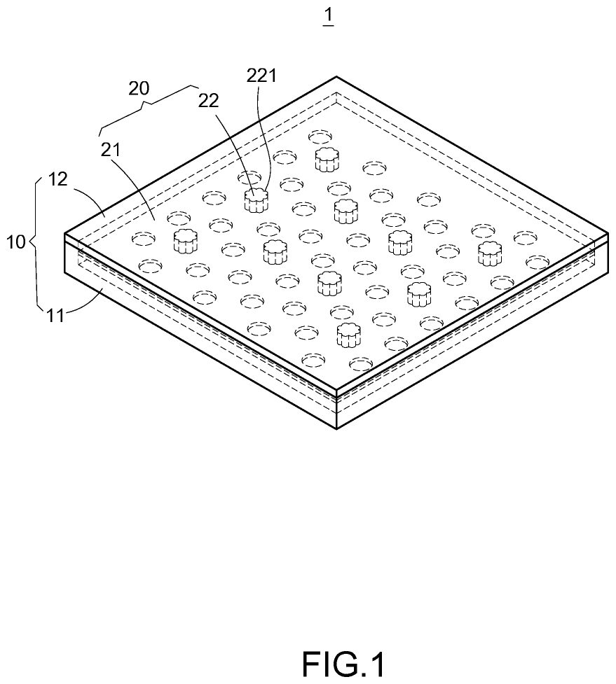

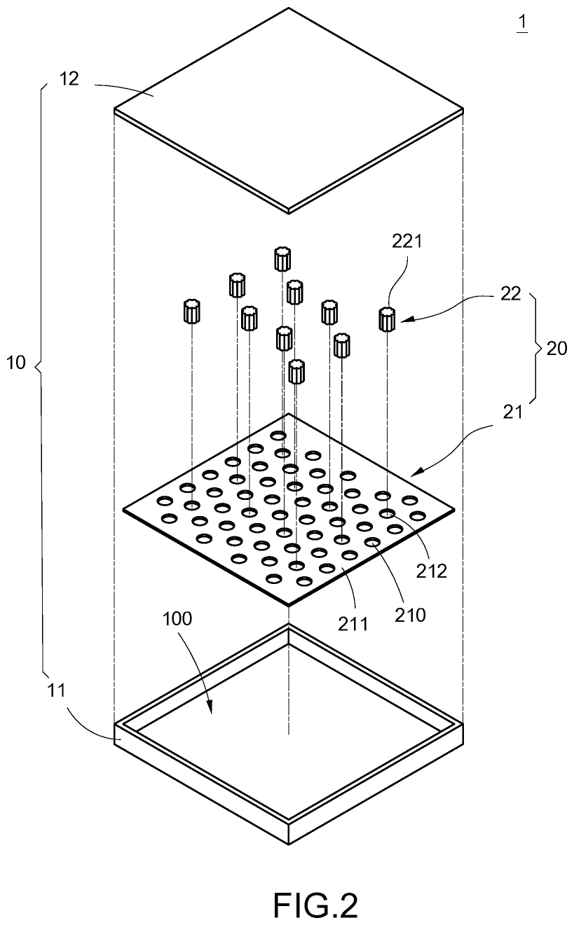

Please refer to FIG. 1 and FIG. 2, showing a perspective see-through view and a perspective exploded view of the vapor chamber of the present disclosure. The present disclosure provides a vapor chamber 1 having a housing 10 and a supporting column securement structure 20. The housing 10 includes an upper cover 11 and a lower cover 12 attached to each other, and also includes a chamber 100. The supporting column securement structure 20 is arranged inside the chamber 100. It should be noted that the internal of the vapor chamber 1 of the present disclosure includes a working fluid therein. The working fluid is not indicated in the drawings.

The supporting column securement structure 20 includes a supporting mesh 21 and a plurality of supporting columns 22. The supporting mesh 21 is arranged inside the chamber 100. The supporting mesh 21 includes a plate 211 with a plurality of mesh holes 210, and the plate 211 includes a plurality of through holes formed thereon 212. To be more specific, the supporting mesh 21 is a metal mesh or a plastic mesh. The arrangement of the supporting mesh 21 is to position the plurality of supporting columns 22.

Furthermore, the outer perimeter of each one of the supporting columns 22 includes at least one positioning portion 221. In addition, each one of the supporting columns 22 penetrates through each one of the through holes 212 of the supporting mesh 21 and is press-fitted at each one of the through holes 212 via the at least one positioning portion 221 to be positioned on the supporting mesh 21.

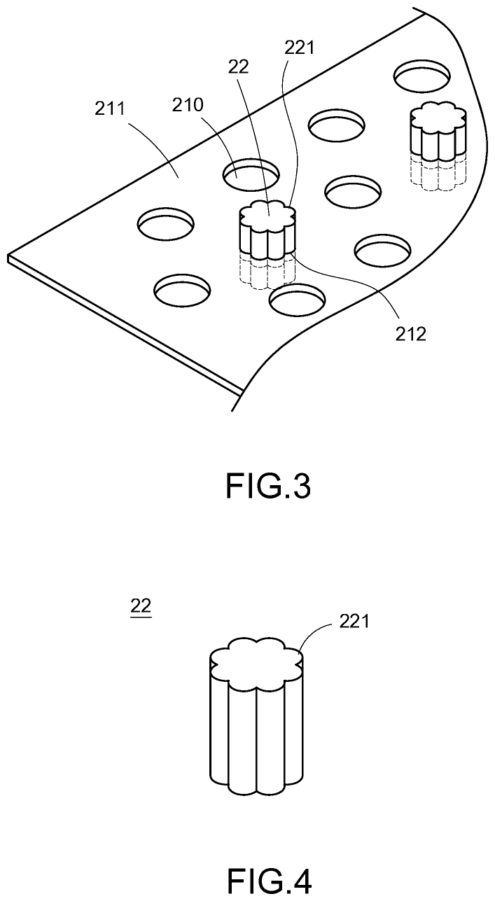

Please refer to FIG. 3 and FIG. 4, showing a partially perspective see-through view of the supporting column securement structure and a perspective appearance view of the supporting column of the present disclosure. In this exemplary embodiment, each one of the supporting columns 22 includes a solid cylindrical shaft. During the actual implementation, it may also be a shaft of other shapes. To be more specific, the outer perimeter of each one of the supporting columns 22 includes a plurality of positioning portion 221. Furthermore, the plurality of positioning portions 221 are connected to each other in a wavy shape and arranged circumferentially at an outer perimeter surface of each one of the supporting columns 22.

It should be noted that in this exemplary embodiment, the dimension of each one of the through holes 212 is slightly smaller than the dimension of each one of the supporting column 22 to make each one of the supporting columns 22 be press-fitted into each one of the through holes 212 without generating any displacement of rotation or wobbling, etc.

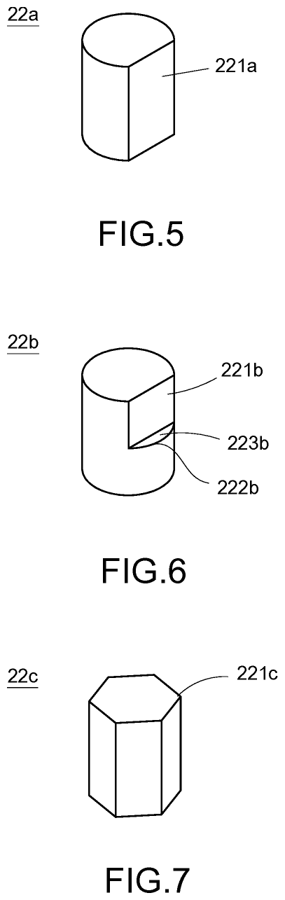

FIG. 5 to FIG. 7 illustrate the supporting column according to other exemplary embodiments of the present disclosure. As shown in FIG. 4, in an exemplary embodiment of the present disclosure, the at least one positioning portion 221a formed on the supporting column 22a is a cut-out slot or a notch. In addition, the at least one positioning portion 221a is extended from one end surface of each one of the supporting columns 22a to another end surface each one of the supporting columns 22a. During actual implementation, the positioning portion 221a may be multiple in number, and the plurality of positioning portions 221a may be formed on the supporting column 22a via the rolling extrusion process.

As shown in FIG. 6, in this exemplary embodiment, the outer perimeter of the supporting column 22b includes at least one positioning portion 221b. In addition, the positioning portion 221b is a cut-out slot, and the positioning portion 221b is extended from one end surface of the supporting column 22b to a middle section position 222b of the supporting column 22b. Furthermore, the supporting column 22b includes a sectioned surface 223b formed at the middle section position 222b. During the actual implementation, the supporting mesh (not shown in the drawings) may abut against the sectioned surface 223b.

As shown in FIG. 7, in this exemplary embodiment, the outer perimeter of the supporting column 22c includes a plurality of positioning portions 221c. To be more specific, the supporting column 22c includes a polygonal shaft and a plurality of positioning portions 221c, and each one of the positioning portions 221c is a corner of the polygonal shaft.

Accordingly, when each one of the supporting columns 22, 22a-22c penetrates through each one of the through holes 221 of the supporting mesh 21, the supporting columns 22, 22a-22c may penetrate through the positioning portions 221, 221a-221c to be press-fitted at the inner edge of each one of the through holes 212 without generating any rotation. As a result, each one of the supporting columns 22, 22a-22c are positioned on the supporting mesh 21 to make the supporting columns 22, 22a-22c be precisely secured at the predefined locations, thereby increasing the yield rate of the vapor chamber.

The above description is provided to illustrate the exemplary embodiments of the present disclosure only such that it shall not be treated as limitation to the claimed scope of the present disclosure. In addition, any equivalent modification made based on the present disclosure shall be considered to be within the claimed scope of the present disclosure.

What is claimed is:

1. A supporting column securement structure of a vapor chamber, arranged inside a housing comprising a chamber, the supporting column securement structure comprising:
a supporting mesh, arranged inside the chamber, comprising a plate with a plurality of mesh holes, and the plate comprising a plurality of through holes disposed thereon; and
a plurality of supporting columns, each one of the supporting columns comprising at least one positioning portion disposed on an outer perimeter thereof, each one of the supporting columns penetrating through each one of the through holes and fitted with each one of the through holes via the at least one positioning portion to be positioned on the supporting mesh.

2. The supporting column securement structure according to claim 1, wherein the at least one positioning portion is a cut-out slot or a notch.

3. The supporting column securement structure according to claim 1, wherein the at least one positioning portion is extended from one end surface of each one of the supporting columns to another end surface of each one of the supporting columns.

4. The supporting column securement structure according to claim 1, wherein the at least one positioning portion is extended from one end surface of each one of the supporting columns to a middle section position of each one of the supporting columns.

5. The supporting column securement structure according to claim 4, wherein each one of the supporting columns comprises a sectioned surface disposed on the middle section position, and the supporting mesh abuts against the sectioned surface.

6. The supporting column securement structure according to claim 1, wherein each one of the supporting columns comprises a plurality of positioning portions, and the plurality of positioning portions are connected to each other in a wavy shape and arranged circumferentially on an outer perimeter surface of each one of the supporting columns.

7. The supporting column securement structure according to claim 1, wherein each one of the supporting columns comprises a solid cylindrical shaft.

8. The supporting column securement structure according to claim 1, wherein each one of the supporting columns comprises a polygonal shaft and a plurality of positioning portions, and each one of the positioning portions is a corner of the polygonal shaft.

9. A vapor chamber, comprising:
a housing, comprising a chamber; and
a supporting column securement structure, arranged inside the chamber and comprising:
a supporting mesh, arranged inside the chamber, comprising a plate with a plurality of mesh holes, and the plate comprising a plurality of through holes disposed thereon; and
a plurality of supporting columns, each one of the supporting columns comprising at least one positioning portion disposed on an outer perimeter thereof, each one of the supporting columns penetrating through each one of the through holes and fitted with each one of the through holes via the at least one positioning portion to be positioned on the supporting mesh.

10. The vapor chamber according to claim 9, wherein the housing comprises an upper cover and a lower cover attached to each other.

11. The vapor chamber according to claim 9, wherein the at least one positioning portion is a cut-out slot or a notch.

12. The vapor chamber according to claim 9, wherein the at least one positioning portion is extended from one end surface of each one of the supporting columns to another end surface of each one of the supporting columns.

13. The vapor chamber according to claim 9, wherein the at least one positioning portion is extended from one end surface of each one of the supporting columns to a middle section position of each one of the supporting columns.

14. The vapor chamber according to claim 13, wherein each one of the supporting columns comprises a sectioned surface disposed on the middle section position, and the supporting mesh abuts against the sectioned surface.

15. The vapor chamber according to claim 9, wherein each one of the supporting columns comprises a plurality of positioning portions, and the plurality of positioning portions are connected to each other in a wavy shape and arranged circumferentially on an outer perimeter surface of each one of the supporting columns.

16. The vapor chamber according to claim 9, wherein each one of the supporting columns comprises a solid cylindrical shaft.

17. The vapor chamber according to claim 9, wherein each one of the supporting columns comprises a polygonal shaft and a plurality of positioning portions, and each one of the positioning portions is a corner of the polygonal shaft.
